(19) United States
(12) Patent Application Publication
(10) Pub. No.: US 2026/0223753 A1
(43) Pub. Date: Jul. 30, 2026

(54) ELECTRONIC DEVICE AND A METHOD FOR MAKING THE SAME

(71) Applicant: STATS ChipPAC Management Pte. Ltd., Singapore (SG)

(72) Inventors: InSeop LIM, Incheon (KR); JuHeun YUN, Incheon (KR)

(21) Appl. No.: 19/452,279

(22) Filed: Jan. 17, 2026

(30) Foreign Application Priority Data
Jan. 24, 2025 (CN) 202510119719.5

(51) Int. Cl. H10W 90/00; H10W 70/60; H10W 72/00; H10W 90/15

(52) U.S. Cl. CPC H10W 90/724; H10W 70/614; H10W 72/01253; H10W 90/15; H10W 90/401; H10W 72/823; H10W 90/7295

(57) ABSTRACT

An electronic device and a method for forming the same are provided. The electronic device comprises: a first substrate; a plurality of electronic components mounted on the first substrate; a plurality sets of conductive structures, wherein each set of conductive structures are formed on and electrically connected with one of the plurality of electronic components such that respective top surfaces of the plurality sets of conductive structures are flush with each other; and a second substrate having a plurality sets of conductive pads formed thereon, wherein each set of conductive pads are mounted on one set of the plurality sets of conductive structures via a set of solder bumps, such that the second substrate is mounted with and electrically connected with the first substrate via the plurality of electronic components, the plurality sets of conductive structures and the plurality sets of conductive pads.

### TECHNICAL FIELD

The present application relates generally to semiconductor technology, and more particularly, to an electronic device and a method for making the same.

### BACKGROUND OF THE INVENTION

The semiconductor industry is constantly faced with complex integration challenges as consumers want their electronics to be smaller, faster and higher performance with more and more functionalities packed into a single device. For example, semiconductor devices with multiple functionalities may be formed by stacking substrates having various electronic components thereon together. To be more specific, in such a semiconductor device, one substrate may be stacked on a base substrate to sandwich the various electronic components therebetween, and the various electronic components are mounted onto the base substrate via solder bumps. The formation of the solder bumps may include a reflowing process of solder pastes formed between the base substrate and the electronic components, which enables efficient electrical connection between them. However, after the reflowing process, the solder bumps may have defects such as non-wetting issues and solder short circuit issues. These defects may be resulted from non-uniform soldering of the solder pastes between the various electronic components and the base substrate, thereby adversely affecting the quality of the electrical connection.

Therefore, a need exists for an electronic device with reduced soldering defects and an improved connection quality.

### SUMMARY OF THE INVENTION

An objective of the present application is to provide an electronic device with reduced soldering defects and an improved connection quality.

According to an aspect of the present application, an electronic device is provided. The electronic device comprises a first substrate; a plurality of electronic components mounted on the first substrate; a plurality sets of conductive structures, wherein each set of conductive structures are formed on and electrically connected with one of the plurality of electronic components such that respective top surfaces of the plurality sets of conductive structures are flush with each other; and a second substrate having a plurality sets of conductive pads formed thereon, wherein each set of conductive pads are mounted on one set of the plurality sets of conductive structures via a set of solder bumps, such that the second substrate is mounted with and electrically connected with the first substrate via the plurality of electronic components, the plurality sets of conductive structures and the plurality sets of conductive pads.

According to another aspect of the present application, a method for making an electronic device is provided. The method comprises providing a first substrate; mounting a plurality of electronic components on the first substrate; forming a plurality sets of conductive structures on the plurality of electronic components, respectively; grinding the plurality sets of conductive structures to flush their top surfaces with each other; and mounting a second substrate having a plurality sets of conductive pads formed thereon with the first substrate by mounting each set of conductive pads on one set of the plurality sets of conductive structures via a set of solder bumps, such that the second substrate is electrically connected with the first substrate via the plurality of electronic components, the plurality sets of conductive structures and the plurality sets of conductive pads.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates an electronic device according to a first embodiment of the present application.

FIG. 2 illustrates an electronic device according to a second embodiment of the present application.

FIG. 3 illustrates an electronic device according to a third embodiment of the present application.

FIGS. 4A to 4F illustrate various steps of a method for making an electronic device according to a fourth embodiment of the present application.

FIGS. 5A to 5D illustrate various steps of a method for making an electronic device according to a fifth embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in a stacked electronic device, one substrate with various electronic components thereon may be stacked on a base substrate by mounting the electronic components onto the base substrate via solder bumps. The formation of the solder bumps may include a reflowing process of solder pastes formed between the base substrate and the electronic components to establish electrical connections therebetween. In some cases, the various electronic components may have different structures, such as different heights. After the reflowing process of the solder pastes, the solder bumps between the electronic components with smaller heights and the base substrate may have non-wetting issues or have voids. In some other cases, solder pastes with larger volumes may be applied to mitigate the non-wetting issues. However, the larger solder pastes on the electronic components may result in bridging of the solder bumps formed by the solder pastes, thereby causing short circuit issues within the electronic device. In addition, during the reflowing process, the electronic components with different heights may displace to different extents, which may result in non-uniform structures of the solder bumps. These defects may adversely affect the quality of the electrical connection between the various electronic components and the base substrate as well as the reliability of the electronic device so formed.

To address the above issue, an electronic device and a method for forming the electronic device are provided according to some embodiments of the present application. The electronic device includes a first substrate and electronic components mounted thereon. A plurality sets of conductive structures are formed on the electronic components, and each set of conductive structures are electrically connected with one of the electronic components such that respective top surfaces of the conductive structures are flush with each other. A second substrate may then be mounted on and electrically connected with the conductive structures. In this way, the conductive structures can compensate for a difference in size among the various electronic components, so as to provide a flat surface for a more uniform structure of an electrical connection between the conductive structures and the second substrate, thereby reducing defects and improving reliability of the electronic device.

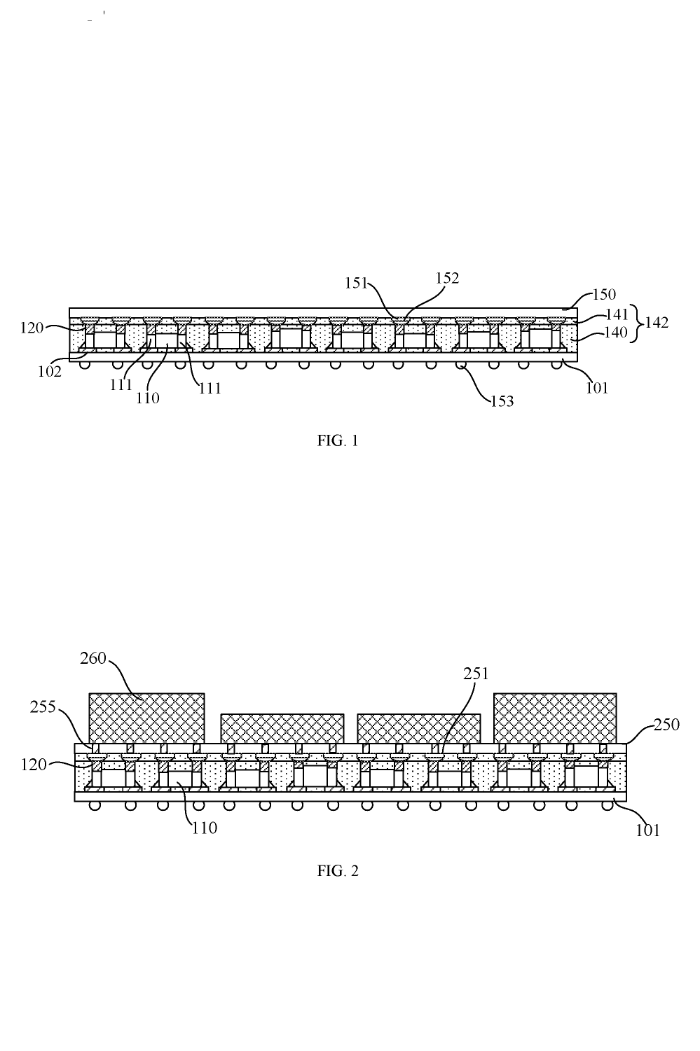

FIG. 1 illustrates an electronic device according to a first embodiment of the present application.

As shown in FIG. 1, the electronic device has a double-layer structure with a plurality of electronic components 110 mounted between a first substrate 101 and a second substrate 150, and the electronic components 110 are electrically connected with both of the two substrates 101, 150.

To be more specific, the first substrate 101 may include a first surface facing upward in the direction shown in FIG. 1, which may serve as a platform where the electronic components 110 can be mounted. And the first substrate 101 also includes a second surface opposite to the first surface. In some embodiments, the first substrate 101 may be made of silicon or other semiconductor materials, or may include a printed circuit board (PCB), a carrier substrate, a ceramic substrate, a laminate interposer, a strip interposer, a leadframe, or other suitable substrates. In some examples, the first substrate 101 may include redistribution layers or structures having one or more dielectric layers and one or more conductive layers between and through the dielectric layers. Thus, various components and other structures on either one surface or both surfaces of the first substrate 101 may be electrically coupled with each other to form an integrated electronic system. In some embodiments, a plurality sets of conductive pads 102 can be formed on the first surface of the first substrate 101 for the mounting of the electronic components 110. It also can be appreciated that the first set of conductive pads 102 may be exposed portions of interconnect wires formed within the first substrate 101.

As shown in FIG. 1, the plurality of electronic components 110 are mounted on the first surface of the first substrate 101 via the plurality sets of conductive pads 102, and each of the electronic components 110 is mounted on one set of the plurality sets of conductive pads 102 on the first substrate 101. In some embodiments, each of the plurality of electronic components 110 may have two terminals 111 each extending from its top surface to its bottom surface. The terminals 111 are used for establishing electrical connections or transmitting signals from module(s) mounted on the top surface of the electronic component 110 to module(s) mounted on the bottom surface of the electronic component 110. In some embodiments, the two terminals 111 are arranged on two opposite sides of the electronic component 110. Each set of the plurality sets of conductive pads 102 may include two conductive pads 102. The two terminals 111 are attached on the two conductive pads 102 respectively, for example, by solder bumps.

In some embodiments, the electronic components 110 may be passive components, such as resistors, capacitors, inductors, etc. It can also be appreciated that the electronic components 110 may be other types of electronic modules, such as semiconductor dice, semiconductor packages, or a semiconductor chip having a more complicated structure. For example, the electronic components 110 may include a large-scale semiconductor chip, an electronic package stack with multi-layer structures, or an electronic package having multiple electronic modules integrated therein. The electronic components 110 may be of a same type or of various different types.

In addition, the electronic components 110 may have different sizes and layouts according to specific designs of the electronic device. In some embodiments, as shown in FIG. 1, the electronic components 110 may have different heights. It can be appreciated that in the electronic device, at least two of the electronic components 110 may have different heights from each other, with the rest having a same height. Therefore, top surfaces of the electronic components 110 may have different heights with relative to the top surface of the first substrate 101 and are not flush with each other.

Furthermore, the electronic device includes a plurality sets of conductive structures 120, and each set of conductive structures 120 are formed on and electrically connected with one of the electronic components 110, for example, by solder bumps. In some embodiments, as shown in FIG. 1, the conductive structures 120 may be conductive pillars 120 (e.g., Cu pillars), and each set of the conductive structures 120 may include two conductive pillars 120 which are formed on top surfaces of the two terminals 111 of the respective electronic component 110. The two conductive pillars 120 formed on the same electronic component 110 have the same height. The heights of the plurality sets of conductive pillars 120 are different for the electronic components 110 with different heights. For example, the set of conductive pillars 120 on the electronic component 110 with a smaller height may have a larger height, compared with another set of conductive pillars 120 on a higher electronic component 110. In this way, the plurality sets of conductive structures 120 may compensate for the differences in height for the electronic components 110, such that respective top surfaces of the plurality sets of conductive structures 120 are flush with each other. Therefore, the plurality sets of conductive structures 120 may help to provide a flat surface for a more uniform structure of electrical connections between the plurality sets of conductive structures 120 and the second substrate 150, thereby reducing defects and improving reliability of the electronic device. Preferably, the two conductive pillars 120 may have a width similar to or slightly smaller than that of the two terminals 111. The conductive pillars 120 may occupy almost an entirety of the top surfaces of the respective terminals 111. It can also be appreciated that the conductive pillars 120 may occupy only a portion of the top surfaces of the respective terminals 111.

In some other embodiments, the plurality of electronic components 110 may have a same height. In these cases, the plurality sets of conductive structures 120 with different heights may still be useful in providing a flat surface that improves uniformity of electrical connections between the conductive structures 120 and the second substrate 150.

Moreover, the electronic device further includes an encapsulant material 140, which is on the first substrate 101 to encapsulate the conductive pads 102, the electronic components 110, and the conductive structures 120. A top surface of the encapsulant material 140 is flush with the top surfaces of the conductive structures 120. In this way, the top surface of the encapsulant material 140 and the top surfaces of the conductive structures 120 together provide a flat surface for mounting of the second substrate 150.

As shown in FIG. 1, the second substrate 150 has a plurality sets of conductive pads 151 formed thereon. The second substrate 150 may include a first surface and a second surface opposite to the first surface. The plurality sets of conductive pads 151 are formed on the first surface of the second substrate 150. The second substrate 150 may include structure(s) and material(s) similar as the first substrate 101. For example, the second substrate 150 may include redistribution layers or structures having one or more dielectric layers and one or more conductive layers between and through the dielectric layers. Thus, various components and other structures on either one surface or both surfaces of the second substrate 150 may be electrically coupled with each other. It also can be appreciated that the plurality sets of conductive pads 151 may be exposed portions of interconnect wires formed within the second substrate 150.

In this embodiment, each set of conductive pads 151 are mounted on one set of the plurality sets of conductive structures 120 via a set of solder bumps 152. As such, the electronic components 110 are electrically connected with the second substrate 150 via the plurality sets of conductive pads 151 and the plurality sets of conductive structures 120. In other words, the second substrate 150 is mounted with and electrically connected with the first substrate 101 via the plurality of electronic components 110, the plurality sets of conductive structures 120 and the plurality sets of conductive pads 151 to form an integrated electronic system. Since the plurality sets of conductive structures 120 are flush with each other, electrical connections between the plurality sets of conductive pads 151 and the plurality sets of conductive structures 120 can have a uniform structure within the electronic device. In addition, in some embodiments, the solder bumps 152 and the conductive pads 151 on the second substrate 150 are encapsulated by an additional encapsulant material 141, which is connected with the encapsulant material 140. Therefore, the encapsulant material 140 and the additional encapsulant material 141 together form an encapsulating layer 142 between the first substrate 101 and the second substrate 150. In some embodiments, the encapsulant material 140 and the additional encapsulant material 141 are formed in sequential processes. It can also be appreciated that the encapsulating layer 142 may alternatively be an integral piece which is formed in a single process.

In addition, additional solder bumps 153 may be formed on the second surface of the first substrate 101 for mounting the electronic device onto an external electronic module. The additional solder bumps 153 may be electrically connected with the conductive pads 102 and/or the redistribution structures on the first substrate 101, such that the electronic components 110 and the second substrate 150 can be accessed through the additional solder bumps 153.

In some other embodiments, additional electronic modules may be attached on the second surface of the second substrate 150, so as to increase an integration level of the electronic device.

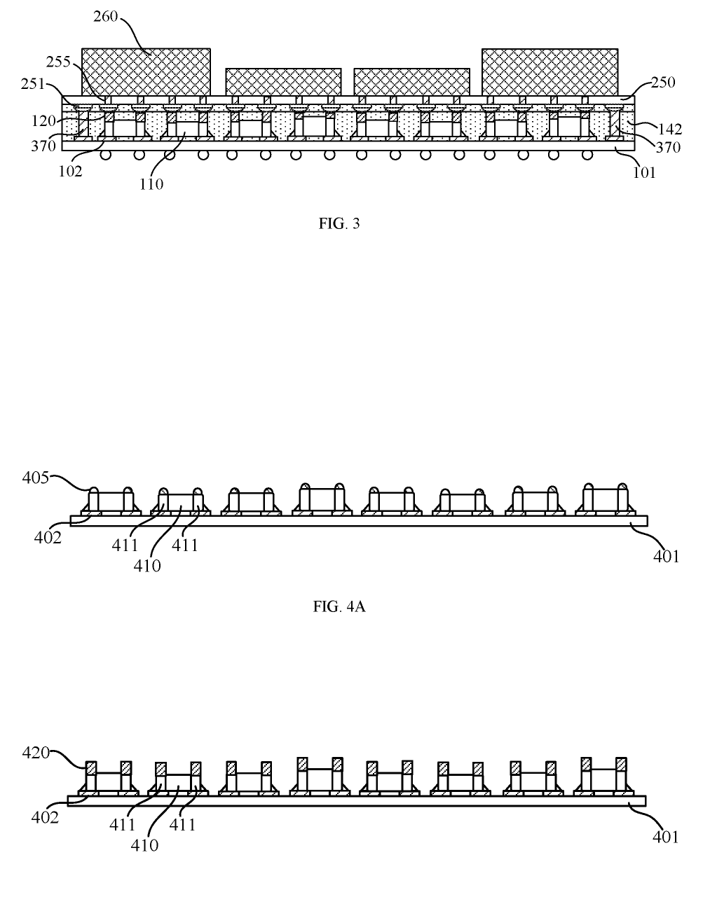

FIG. 2 illustrates an electronic device according to a second embodiment of the present application. The electronic device shown in FIG. 2 has generally the same structure(s) and material(s) as the electronic device shown in FIG. 1, except that the electronic device in FIG. 2 further includes one or more additional electronic modules 260 formed on a second substrate 250 of the electronic device.

As shown in FIG. 2, the second substrate 250 further includes at least one set of conductive vias 255 extending through the second substrate 250. To be more specific, a top surface and a bottom surface of each of the conductive vias 255 are exposed from a first surface and a second surface of the second substrate 250, respectively. Each set of the at least one set of conductive vias 255 are aligned with and electrically connected with one set of the plurality sets of conductive pads 251 formed on the first surface of the second substrate 250. Each additional electronic module 260 is mounted on the second surface of the second substrate 250 and is electrically connected with at least one set of conductive pads 251 through at least one respective set of conductive vias 255. Therefore, the additional electronic module 260 is electrically connected with at least one electronic component 110 through the respective set(s) of conductive vias 255, the respective set(s) of conductive pads 251, and at least one respective set of conductive structures 120 on the electronic component 110. In this way, the conductive vias 255 may provide a direct connection path from the electronic components 110, which are encapsulated between the second substrate 250 and the first substrate 101, to the additional electronic module 260 on the second surface of the second substrate 250. The conductive vias 255 may provide more potential nodes for direct mounting of the additional electronic module 260, such that the additional electronic module 260 can be placed right above or close to the electronic components 110, thereby increasing an integration level of the electronic device.

Additionally, the conductive vias 255 may also simplify a wiring layout for the connections between the additional electronic module 260 and the electronic component(s) 110.

In some preferred embodiments, the second substrate 250 includes a plurality sets of conductive vias 255 which are aligned with all the plurality sets of conductive pads 251 respectively. More than one additional electronic modules 260 are mounted on the second substrate 250, and are electrically connected with all the electronic components 110 through the plurality sets of conductive vias 255 and the plurality sets of conductive pads 251, as shown in FIG. 2. In some other embodiments, the plurality sets of conductive vias 255 are electrically connected with only a portion of the conductive pads 251, and thus are electrically connected with a portion of the electronic components 110.

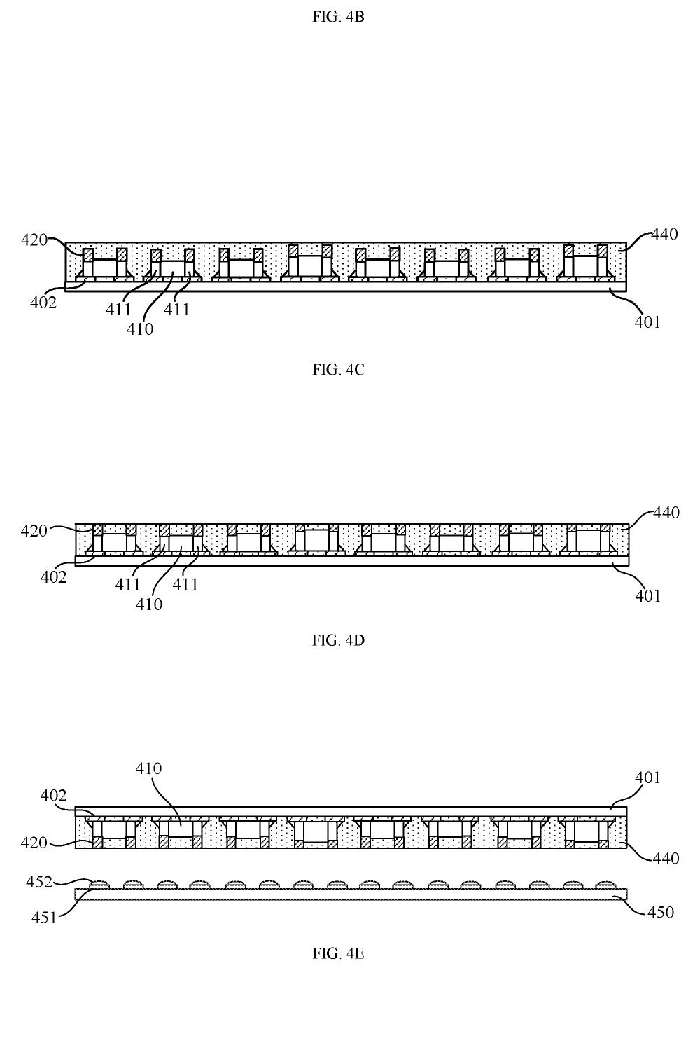

FIG. 3 illustrates an electronic device according to a third embodiment of the present application.

The electronic device shown in FIG. 3 has generally the same structure(s) and material(s) as the device shown in FIG. 2, except that the electronic device in FIG. 3 further includes one or more interconnect structures 370 extending from a first substrate 101 to a second substrate 250 through an encapsulating layer 142. In some preferred embodiments, a top surface of the interconnect structure 370 may be flush with top surfaces of conductive structures 120, and the interconnect structure 370 are also formed between the first and second substrate 101 and 250. In addition, a bottom surface and a top surface of the interconnect structure 370 may be attached onto respective conductive pads 102, 251 of the first and second substrates 101 and 250. In this way, the interconnect structure 370 establishes a direct electrical connection between the first substrate 101 and the second substrate 250, which provides an additional electrical pathway within the electronic device. In other words, apart from conductive vias 255 that extend through the second substrate 250, an additional electronic module 260 on the second substrate 250 can be electrically connected with the first substrate 101 via the interconnect structure 370. In some embodiments, the interconnect structure 370 may be formed within a peripheral region between the first and second substrates 101, 250 and surrounding the electronic components 110. In some other embodiments, the interconnect structure 370 may also be formed among the electronic components 110 depending on an actual layout of the electronic device.

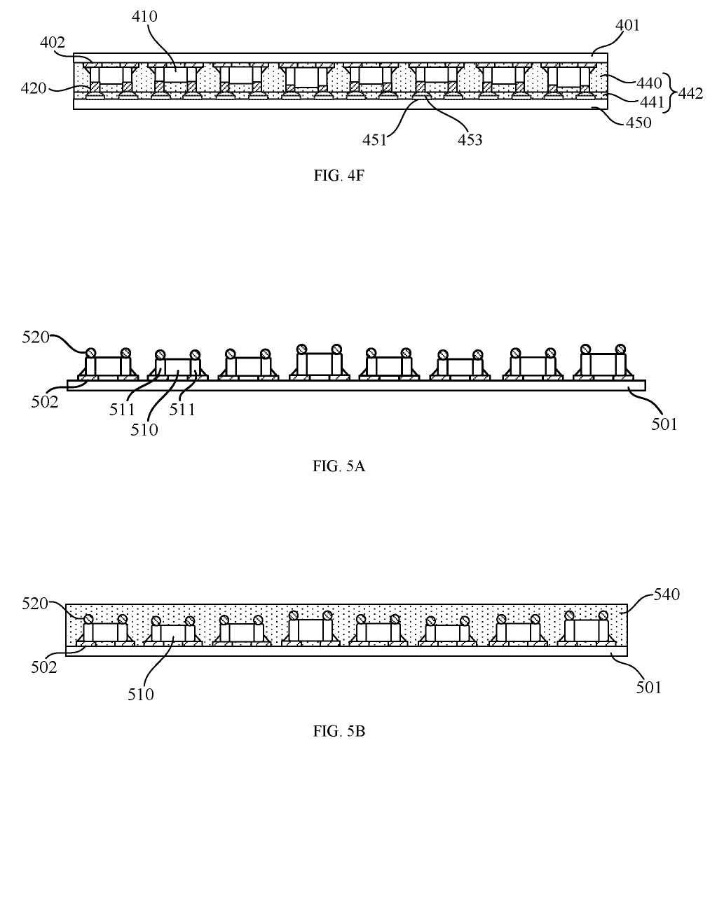

FIGS. 4A to 4F illustrate various steps of a method for making an electronic device according to a fourth embodiment of the present application. The electronic device may be similar to the electronic device illustrated in FIG. 1, FIG. 2 or FIG. 3.

As shown in FIG. 4A, a first substrate 401 is provided with a first surface facing upward and a second surface opposite to the first surface facing downward. In some examples, the first substrate 401 may include redistribution layers or structures having one or more dielectric layers and one or more conductive layers between and through the dielectric layers. Furthermore, a plurality sets of conductive pads 402 may be formed on the first surface of the first substrate 401 for mounting of electronic components, as will be elaborated below.

Next, a plurality of electronic components 410 are mounted on the first surface of the first substrate 401 via the conductive pads 402. To be more specific, each of the electronic components 410 is mounted on one set of the plurality sets of conductive pads 402 on the first substrate 401. In some embodiments, each of the plurality of electronic components 410 may have two terminals 411, and each of the two terminals 411 extends from a top surface to a bottom surface of the respective electronic component. Each set of the sets of conductive pads 402 on the first substrate 401 may include two conductive pads 402. Thus, the two terminals 411 are attached on the two conductive pads 402, for example, by solder bumps. In some embodiments, the electronic components 410 may have different heights. Therefore, top surfaces of the electronic components 410 may not be flush with each other.

Next, a solder paste 405 is dispensed on the top surface of each of the electronic components 410. In particular, the solder pastes 405 are generally dispensed on respective top surfaces of the two terminals 411 of the respective electronic component 410. In some embodiments, the solder paste 405 may include a metal solder material such as tin and a flux material. Preferably, an overall surface of the metal solder material may be coated by the flux material, which promotes efficiency of a subsequent reflowing process to the metal solder material.

Next, as shown in FIG. 4B, a plurality sets of conductive structures 420 are formed on the plurality of electronic components 410, respectively, with the solder pastes 405 dispensed therebetween. To be more specific, each set of conductive structures 420 are formed on one of the electronic components 410. In some embodiments, the conductive structures 420 may be conductive pillars 420, and each set of conductive structures 420 may include two conductive pillars 420 which are formed on the top surfaces of the two terminals 411 of the respective electronic component 410. The plurality sets of conductive pillars 420 on the different electronic components 410 may have the same height or different heights. In addition, a minimum height of top surfaces of the plurality sets of conductive structures 420 is at least larger than the height of the top surface(s) of the shortest electronic component(s) with relative to the first substrate 401.

In some embodiments, each of the conductive pillars 420 is a pre-formed module. All the conductive pillars 420 may have a same height. The conductive pillars 420 are placed on the electronic components 410, for example, by a grasper. In some embodiments, an alignment mark may be formed on the first substrate 401 or on the top surface of one electronic component 410 to guarantee the alignment between the plurality sets of conductive pillars 420 and the electronic components 410, respectively. It can also be appreciated that the plurality sets of conductive pillars 420 may have different heights. For example, the sets of conductive pillars 420 formed on higher electronic components 410 may have smaller heights, and the sets of conductive pillars 420 formed on shorter electronic components 410 may have larger heights.

In some other embodiments, a frame with a grid pattern may be introduced to facilitate the placement of the conductive pillars 420 onto the electronic components 410. To be more specific, the grid pattern may include a plurality of openings aligned with at least a portion of the top surfaces of the electronic components 410, for example, the top surfaces of the terminals 411 of the electronic components 410, respectively. During the placement of the conductive pillars 420, the frame may be placed onto the top surfaces of the electronic components 410 or the first surface of the first substrate 401. Then each of the conductive pillars 420 may be inserted into one of the openings of the frame and be placed onto the terminal 411 of the respective one of the electronic components 410 with improved accuracy and efficiency. In addition, the frame may also avoid the risk of tilting of the conductive pillars 420 during the mounting process.

In some alternative embodiments, the plurality sets of conductive structures 420 may be formed through a patterning process instead of a pre-forming procedure. To be more specific, after the mounting of the electronic components 410 on the first substrate 401, a protection layer is attached on the first substrate 401 to cover all respective surfaces of the electronic components 410. Next, a patterned mask may be formed on the protection layer, which has a plurality of openings passing therethrough and aligned with the terminals 411 of the electronic components 410 respectively. Next, a portion of the protection layer is etched corresponding to the plurality of openings of the patterned mask to form a plurality of openings within the protection layer. As such, each opening within the protection layer may expose at least a portion of the top surface of the terminal 411 of one electronic component 410. Next, a conductive material is deposited within the plurality of openings to form a plurality of conductive structures 420 such as a plurality of conductive pillars 420. Next, the protection layer may be removed from the first substrate 401, the conductive structures 420 and the electronic components 410, leaving only the conductive pillars 420.

Next, a reflowing process may be implemented to reflow the solder pastes between the electronic components 410 and the conductive structures 420 to form respective solder bumps, which can electrically connect the electronic components 410 with the conductive structures 420, respectively.

Next, as shown in FIG. 4C, an encapsulant material 440 is formed on the first substrate 401 to encapsulate the plurality sets of conductive pads 402, the plurality of electronic components 410 and the plurality sets of conductive structures 420. The encapsulant material 440 covers the top surfaces of the plurality sets of conductive structures 420. The formation of the encapsulant material 440 may include a melting process that melts a molding compound, and a curing process that solidifies the melted molding compound into the encapsulant material 440. Both the melting process and the curing process can be conducted by applying a heating process to the entire device.

Next, as shown in FIG. 4D, a grinding process is implemented to the encapsulant material 440 and the plurality sets of conductive structures 420. To be more specific, during the grinding process, the encapsulant material 440 may first be grinded at its top surface to expose at least one set of conductive structures 420. Then the grinding process continues to grind the encapsulant material 440 and the conductive structures 420 together to expose more sets of conductive structures 420. The grinding process can be ended after all sets of conductive structures 420 are exposed from the encapsulant material 440. In some embodiments, a monitor or sensor may be used to detect when all sets of conductive structures 420 are exposed. After the grinding process, the top surfaces of the plurality sets of conductive structures 420 and the top surface of the encapsulant material 440 are flush with each other. The plurality sets of conductive structures 420 may compensate for differences in height of the electronic components. The plurality sets of conductive structures 420 and the encapsulant material 440 provide a flat surface for mounting of additional modules, thereby reducing defects and improving reliability of the electronic device.

Next, as shown in FIG. 4E, a second substrate 450 with a plurality sets of conductive pads 451 formed thereon is provided. The second substrate 450 may include a first surface where the plurality sets of conductive pads 451 are formed, and a second surface opposite to the first surface. An additional solder paste 452 is dispensed on each set of conductive pads 451. Next, as shown in FIG. 4F, the first surface of the second substrate 450 may face towards the top surface of the encapsulant material 440 and the top surfaces of the conductive structures 420, so as to attach the plurality sets of conductive pads 451 onto the plurality sets of conductive structures 420 respectively. To be more specific, each set of conductive pads 451 are attached on one set of the plurality sets of conductive structures 420 with the solder pastes 452 dispensed therebetween. Next, a reflowing process may be implemented to reflow the solder paste 452 to form a plurality sets of solder bumps 453, which electrically connect the plurality sets of conductive structures 420 and the plurality sets of conductive pads 451, respectively. A cleaning process may then be conducted to remove residuals of the flux material after the reflowing process.

Next, an additional encapsulant material 441 is formed between the encapsulant material 440 and the second substrate 450 to encapsulate the solder bumps 453 and the conductive pads 451. The encapsulant material 440 and the additional encapsulant material 441 together form an overall encapsulating layer 442 between the first substrate 401 and the second substrate 450. In this way, the electronic device is formed. In some embodiments, additional solder bumps may be formed on the second surface of the first substrate 401 for mounting the electronic device onto an external electronic module. The details of the structures and materials of the electronic device may be similar as the electronic device shown in FIG. 1, which will not be elaborated in detail here for simplicity.

In the embodiment shown in FIGS. 4D to 4F, the encapsulant material 440 and the additional encapsulant material 441 are formed in processes after the formation of the conductive structures 420. In some other embodiments, the plurality sets of conductive structures 420 are grinded to flush their top surfaces with each other before the formation of the encapsulant material 440 on the first substrate 401. After the second substrate 450 is mounted with and electrically connected with the first substrate 401, an encapsulating layer 442 is formed between the first substrate 401 and the second substrate 450 as an integral piece in a single process to encapsulate the plurality of electronic components 410, the plurality sets of conductive structures 420, the plurality sets of conductive pads 402, 451 between the first and second substrates 401, 450.

In some other embodiments, additional electronic module(s) may be attached on the second surface of the second substrate 450, so as to increase an integration level of the electronic device. The details of the structures and materials of the electronic device may be similar as the electronic device shown in FIG. 2, which will not be elaborated in detail here for simplicity.

In some further embodiments, before the formation of the encapsulant material 440, at least one interconnect structure is formed on the first substrate 401. A top surface of each of the at least one interconnect structure may be grinded together with the conductive structures 420 to flush their top surfaces with each other. During the mounting of the second substrate with the conductive structures, the at least one interconnect structure may also be mounted on and connected with the second substrate via at least one set of conductive pads on the second substrate. The details of the structures and materials of the electronic device may be similar as the electronic device shown in FIG. 3, which will not be elaborated in detail here for simplicity.

In some embodiments, the method illustrated in FIGS. 4A to 4F may be used to form an electronic device array including a plurality of electronic devices which are similar or identical with each other. The electronic device array may then be separated into more than one electronic devices through a singulation process. Each of the electronic devices includes more than one electronic components 410.

Moreover, in some alternative embodiments, the conductive structures may have other forms, such as e-bars or solder bumps. An example of such alternative conductive structures is provided below.

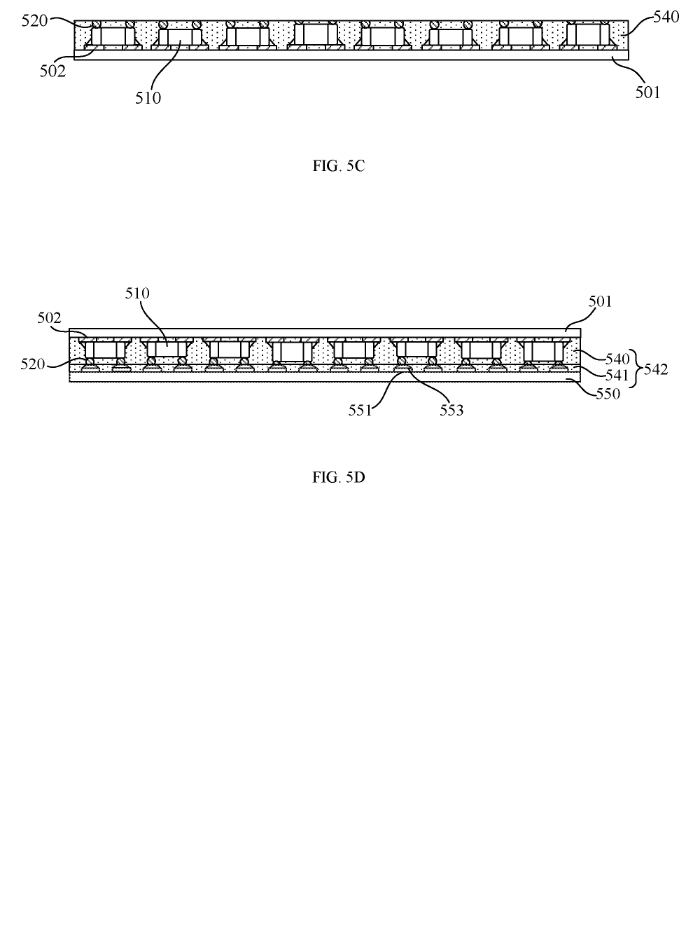

FIGS. 5A to 5D illustrate various steps of a method for making an electronic device according to a fifth embodiment of the present application. The electronic device so formed is the same as the electronic device formed by the method illustrated in FIGS. 4A to 4F, except that in FIGS. 5A to 5D, conductive structures included within the electronic device are solder bumps instead of the conductive pillars 420 shown in FIG. 4F.

As shown in FIG. 5A, a first substrate 501 is provided with a first surface facing upward and a second surface opposite to the first surface facing downward. A plurality sets of conductive pads 502 may be formed on the first surface of the first substrate 501. Next, a plurality of electronic components 510 are mounted on the first surface of the first substrate 501 via the plurality sets of conductive pads 502. In some embodiments, the electronic components 510 may have different heights. Therefore, top surfaces of the electronic components 510 are not flush with each other. Next, a solder paste (not shown) is dispensed on the top surface of each of the electronic components 510. In some embodiments, the solder paste may include a metal solder material and a flux material.

Next, an additional solder paste is formed on each of the plurality of electronic components 510, respectively. Preferably, the additional solder paste may have a larger volume than that of the solder paste dispensed previously. The additional solder paste may include the same materials as that of the solder paste, i.e., a metal solder material and a flux material.

Next, a reflowing process may be implemented to reflow the additional solder paste and the solder paste, which are then merged together to form a solder bump 520. As such, a plurality sets of solder bumps 520 may be formed and thus mounted on the plurality of electronic components 510, respectively. In some embodiments, each of the plurality of electronic components 510 may have two terminals 511. Each set of the solder bumps 520 include two solder bumps 520 which are formed on respective top surfaces of the two terminals 511 of the electronic component 510. In some embodiments, the solder bumps 520 may have a relatively large diameter, which may be the same as or slightly smaller than a width of the terminals 511. Diameters (or heights) of the plurality sets of solder bumps 520 on different electronic components 510 may be the same or different. In addition, adjacent solder bumps 520 formed on adjacent electronic components 510 are not connected with each other to avoid short circuit issues.

Next, as shown in FIG. 5B, an encapsulant material 540 is formed on the first substrate 501 to encapsulate the plurality sets of conductive pads 502, the plurality of electronic components 510 and the plurality sets of solder bumps 520. The encapsulant material 540 covers top surfaces of the plurality sets of solder bumps 520.

Next, as shown in FIG. 5C, a grinding process is implemented to grind the encapsulant material 540 and the plurality sets of solder bumps 520 at their top surfaces. After the grinding process, the top surfaces of the solder bumps 520 and the top surface of the encapsulant material 540 are flush with each other. To be more specific, all the solder bumps 520 are exposed from the top surface of the encapsulant material 540.

Next, as shown in FIG. 5D, a second substrate 550 with a plurality sets of conductive pads 551 formed thereon is provided. The second substrate 550 may include a first surface where the plurality sets of conductive pads 551 are formed, and a second surface opposite to the first surface. A further solder paste is dispensed on each set of conductive pads 551. Next, the first surface of the second substrate 550 may face towards the top surface of the encapsulant material 540 and the top surfaces of the solder bumps 520, so as to attach the plurality sets of conductive pads 551 onto the plurality sets of solder bumps 520 respectively. To be more specific, each set of conductive pads 551 is attached on one set of the plurality sets of solder bumps 520 encapsulated by the encapsulant material 540, with the further solder paste dispensed therebetween. Next, a reflowing process may be implemented to reflow the further solder paste to form plurality sets of further solder bumps 553 to electrically connect the plurality sets of solder bumps 520 and the plurality sets of conductive pads 551 respectively.

Next, an additional encapsulant material 541 is formed between the encapsulant material 540 and the second substrate 550 to encapsulate the further solder bumps 553 and the conductive pads 551 on the second substrate 550. The encapsulant material 540 and the additional encapsulant material 541 together form an encapsulating layer 542 between the first substrate 501 and the second substrate 550.

The other details of the structures and materials of the electronic device may be similar to those of the electronic devices shown in FIG.1, FIG. 2 or FIG.3, which will not be elaborated in detail here for simplicity.

While the exemplary electronic device and method for making the electronic device of the present application are described in conjunction with corresponding figures, it will be understood by those skilled in the art that modifications and adaptations to the device and method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic device, comprising:
a first substrate;
a plurality of electronic components mounted on the first substrate;
a plurality sets of conductive structures, wherein each set of conductive structures are formed on and electrically connected with one of the plurality of electronic components such that respective top surfaces of the plurality sets of conductive structures are flush with each other; and
a second substrate having a plurality sets of conductive pads formed thereon, wherein each set of conductive pads are mounted on one set of the plurality sets of conductive structures via a set of solder bumps, such that the second substrate is mounted with and electrically connected with the first substrate via the plurality of electronic components, the plurality sets of conductive structures and the plurality sets of conductive pads.

2. The electronic device of claim 1, wherein the plurality of electronic components comprise at least two electronic components having different heights.

3. The electronic device of claim 2, wherein the sets of conductive structures have different heights on the at least two electronic components with different heights.

4. The electronic device of claim 1, wherein the conductive structures comprise conductive pillars.

5. The electronic device of claim 1, wherein the conductive structures comprise solder bumps.

6. The electronic device of claim 1, wherein each of the plurality of electronic components has two terminals each extending from a top surface to a bottom surface of the respective electronic component, and each set of the plurality sets of conductive structures comprise two conductive structures formed on the two terminals of one of the electronic components.

7. The electronic device of claim 1, wherein the second substrate comprises a first surface where the plurality sets of conductive pads are formed, and a second surface opposite to the first surface, and wherein the electronic device further comprises an additional electronic module formed on the second surface of the second substrate.

8. The electronic device of claim 7, wherein the second substrate comprises at least one set of conductive vias extending therethrough, and each set of the at least one set of conductive vias are aligned with one set of the plurality sets of conductive pads to electrically connect the additional electronic module with at least one of the plurality of electronic components.

9. The electronic device of claim 1, wherein the electronic device further comprises an encapsulating layer formed between the first substrate and the second substrate to encapsulate the plurality of electronic components, the plurality sets of conductive structures and the plurality sets of conductive pads.

10. The electronic device of claim 1, wherein the electronic device further comprises an interconnect structure extending from the first substrate to the second substrate to establish a direct electrical connection between the first substrate and the second substrate.

11. A method for making an electronic device, comprising:
providing a first substrate;
mounting a plurality of electronic components on the first substrate;
forming a plurality sets of conductive structures on the plurality of electronic components, respectively;
grinding the plurality sets of conductive structures to flush their top surfaces with each other; and
mounting a second substrate having a plurality sets of conductive pads formed thereon with the first substrate by mounting each set of conductive pads on one set of the plurality sets of conductive structures via a set of solder bumps, such that the second substrate is electrically connected with the first substrate via the plurality of electronic components, the plurality sets of conductive structures and the plurality sets of conductive pads.

12. The method of claim 11, wherein after mounting a plurality of electronic components on the first substrate and before forming a plurality sets of conductive structures on the plurality of electronic components, the method further comprises: dispending a solder paste on the plurality of electronic components.

13. The method of claim 11, wherein after forming a plurality sets of conductive structures on the plurality of electronic components and before mounting a second substrate with the first substrate, the method further comprises:
forming an encapsulant material on the first substrate to encapsulate the plurality of electronic components and the plurality sets of conductive structures; and wherein grinding the plurality sets of conductive structures further comprises:
grinding the plurality sets of conductive structures and the encapsulant material to flush their top surfaces with each other.

14. The method of claim 11, wherein the plurality of electronic components comprise at least two electronic components having different heights.

15. The method of claim 14, wherein the sets of conductive structures have different heights on the at least two electronic components with different heights.

16. The method of claim 11, wherein the conductive structures comprise conductive pillars.

17. The method of claim 11, wherein the conductive structures comprise solder bumps.

18. The method of claim 11, wherein the second substrate comprises a first surface where the plurality sets of conductive pads are formed, and a second surface opposite to the first surface, and wherein the method further comprises: forming an additional electronic module on the second surface of the second substrate.

19. The method of claim 18, wherein the second substrate comprises at least one set of conductive vias extending therethrough, and each set of the at least one set of conductive vias are aligned with one set of the plurality sets of conductive pads; and wherein after mounting the second substrate with the first substrate, the additional electronic module is electrically connected with at least one of the plurality of electronic components.
